(19) United States
(12) Patent Application Publication
(10) Pub. No.: US 2025/0336708 A1
(43) Pub. Date: Oct. 30, 2025

(54) FILM FOR SEMICONDUCTOR PACKAGING

(71) Applicant: Samsung Electronics Co., Ltd., Suwon-si (KR)

(72) Inventor: Hyung Jun Kim, Suwon-si (KR)

(21) Appl. No.: 19/021,308

(22) Filed: Jan. 15, 2025

(30) Foreign Application Priority Data
Apr. 26, 2024 (KR) 10-2024-0056284

(51) Int. Cl. H01L 21/683; C09J 7/29; C09J 7/38

(52) U.S. Cl. CPC H01L 21/6836; C09J 7/29; C09J 7/385; C09J 2203/326; C09J 2301/162; C09J 2301/302

(57) ABSTRACT

A film for semiconductor packaging and a method of manufacturing the film are provided. The film may include a base layer, an intermediate layer, and an adhesive layer, and the intermediate layer may include polyborosiloxane. The film may include a base layer and an adhesive layer, and the adhesive layer may include polyborosiloxane.

### CROSS-REFERENCE TO RELATED APPLICATION

This U.S. non-provisional application claims the benefit of Korean Patent Application No. 10-2024-0056284, filed on Apr. 26, 2024, in the Korean Intellectual Property Office, the entire disclosure of which is incorporated herein by reference in its entirety for all purposes.

### BACKGROUND

### 1. Field of the Invention

One or more embodiments relate to a film for semiconductor packaging.

### 2. Description of the Related Art

In the case of commercialized dicing tapes used in semiconductor packaging, a single layer or multiple layers formed of polyolefin (PO) as a main ingredient are often used as a base material of a tape, and the above layers do not have separate special properties. In addition, in the case of an adhesive layer disposed on the base material, the principle of improving the cohesion of the adhesive layer through photocuring is generally used. However, the stress on the chip is still rapidly increasing when a chip is picked up during a packaging process, even though a simple photocuring strategy is used, which results in an occurrence of a large number of cracks of the chip.

In this situation, recently, with the development of industries related to artificial intelligence (AI), a demand for high bandwidth memory (HBM) is increasing, and the performance of the HBM varies depending on an increase of the number of stacked layers even in the HBM. Thus, the thickness of a manufactured memory chip inevitably increases as the number of stacked layers increases, such as HBM3 8H, HBM4 8H, HBM4 12H, and HBM4 16H.

Therefore, to prevent such an increase in a thickness of a memory chip, the thickness of the memory chip may need to be set to be less than that of existing memory chips. Here, an adhesive force required when a chip is picked up in a semiconductor packaging process needs to be set to be low, at a level less than 20% of the current level (100%).

However, a pick-up characteristic of a chip through simple photocuring of a currently used dicing tape, and the like, has reached a limitation in a reduction in adhesive force. The development of performance of a pressure sensitive adhesive (PSA) itself in an adhesive layer also has faced limitations as the pick-up issue continues.

Therefore, in response to a continuous requirement to decrease the thickness of a multi-layered memory chip, the need to develop films for new concept semiconductor packaging is increasing.

The above information is presented as background information only to assist with an understanding of the disclosure. No determination has been made, and no assertion is made, as to whether any of the above might be applicable as prior art with regard to the disclosure.

### SUMMARY

According to an aspect of the present invention, a film for semiconductor packaging includes a base layer, an intermediate layer, and an adhesive layer.

The film may include an intermediate layer including polyborosiloxane.

According to another aspect of the present invention, a film for semiconductor packaging includes a base layer and an adhesive layer.

The film may include an adhesive layer including polyborosiloxane.

According to another aspect of the present invention, a method of manufacturing a film for semiconductor packaging includes preparing a base layer having first and second base layer surfaces, forming an intermediate layer by coating at least one or both of the first and second base layer surfaces with a polyborosiloxane composition and drying the polyborosiloxane. The method may include forming an adhesive layer on the intermediate layer.

Additional aspects of embodiments will be set forth in part in the present description and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram schematically illustrating an example of a film for semiconductor packaging and main components of the film according to an embodiment;

FIG. 2 is a diagram schematically illustrating another example of a film for semiconductor packaging and main components of the film according to an embodiment;

FIG. 3 is a diagram illustrating example structures of polyborosiloxane included in a film for semiconductor packaging according to an embodiment;

FIG. 4 is a diagram illustrating an adhesive characteristic required for a film for semiconductor packaging according to a development of a semiconductor;

FIG. 5 is a side diagram schematically illustrating a process in which a crack occurs in a chip ejection process;

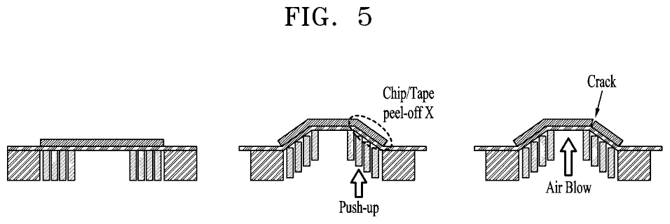

FIG. 6A is a diagram schematically illustrating a portion of a packaging process of a semiconductor chip through chilling and expansion before the semiconductor chip is picked up according to an embodiment;

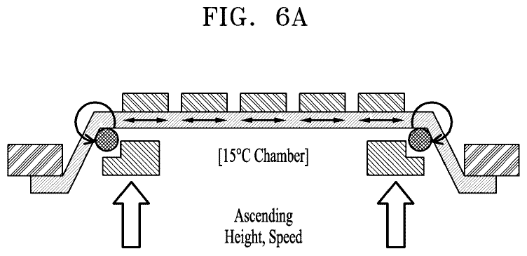

FIG. 6B is a diagram schematically illustrating a phenomenon in which a tape is peeled off from the chip of FIG. 6A on an edge of the chip;

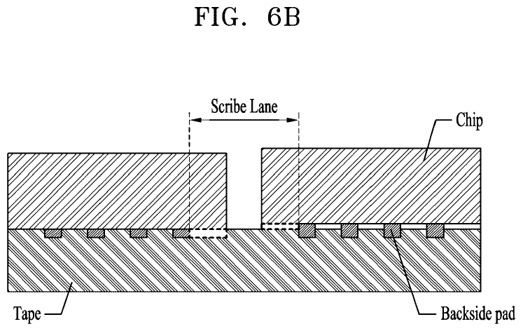

FIG. 7 is a diagram illustrating stress that may occur during a pick-up process when a film according to an embodiment is used as a dicing tape;

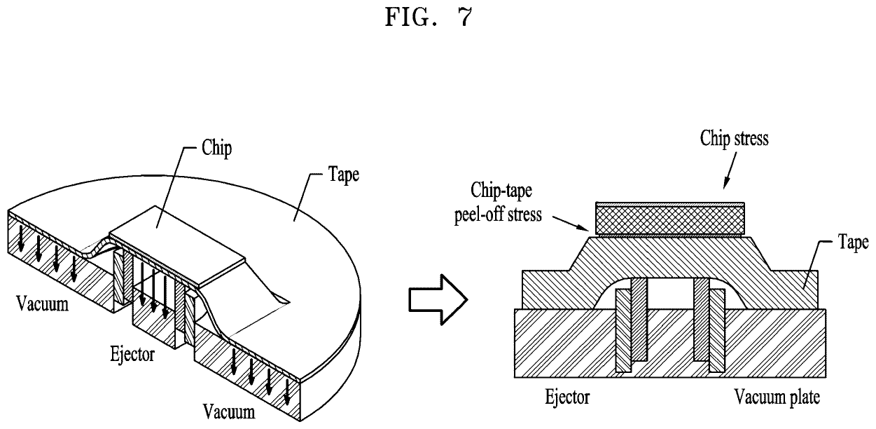

FIG. 8 is a diagram illustrating a change in impregnation properties with an adherend based on a presence or absence of an intermediate layer including polyborosiloxane;

FIG. 9 is a diagram schematically illustrating an example of a film for semiconductor packaging and main components of the film according to an embodiment; and

FIG. 10 is a diagram schematically illustrating another example of a film for semiconductor packaging and main components of the film according to an embodiment.

### DETAILED DESCRIPTION

Hereinafter, embodiments will be described in detail with reference to the accompanying drawings. When describing the embodiments with reference to the accompanying drawings, like reference numerals refer to like components and a repeated description related thereto will be omitted. In the description of embodiments, detailed description of well-known related structures or functions will be omitted.

The expression “semiconductor packaging” used herein encompasses post-processing in a manufacturing of a semiconductor and includes a series of processes including dicing of a wafer to suit the purpose, bonding of wires, and performing of packaging. The expression “for semiconductor packaging” used herein may include an availability in each process included in the series of processes, for example, pick-up or dicing of a semiconductor chip, grinding and transfer of a semiconductor wafer, and the like.

“Semiconductor dicing” may include, for example, forming a groove with a predetermined depth on a surface of a semiconductor wafer by a method, such as blade dicing, laser dicing, or plasma dicing, performing grinding from a back side of the semiconductor wafer, and dividing the wafer by cutting to obtain a semiconductor chip. Here, the surface of the semiconductor wafer may be a surface on which a circuit is formed, and the back side may be a surface on which a circuit is not formed.

In the present disclosure, items described in the singular herein may be provided in plural, as can be seen, for example, in the drawings. Thus, the description of a single item that is provided in plural should be understood to be applicable to the remaining plurality of items unless the context clearly dictates otherwise.

Terms such as “first” and “second” may be used to simply distinguish a corresponding component from other components, and do not limit the components in other aspects (e.g., importance or order). The nature, the sequences, or the orders of the components are not limited by the terms. Unless the context indicates otherwise, these terms are only used to distinguish one element from another element, for example as a naming convention.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

A component, which has the same common function as a component included in any one embodiment, will be described by using the same name in other embodiments. Unless disclosed to the contrary, the configuration disclosed in any one embodiment may be applied to other embodiments, and the specific description of the repeated configuration will be omitted.

Hereinafter, a configuration of each member of a film for semiconductor packaging according to an embodiment is described in detail through implementation examples.

### IMPLEMENTATION EXAMPLE 1

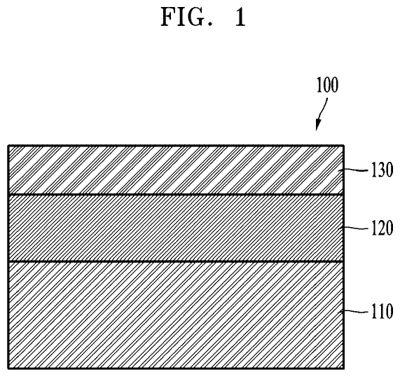

FIG. 1 is a diagram schematically illustrating an example of a film for semiconductor packaging and main components of the film according to an embodiment.

Referring to FIG. 1, in an embodiment, a film 100 for semiconductor packaging may be represented in the form of a laminate including a base layer 110, an intermediate layer 120 stacked on the base layer 110, and an adhesive layer 130 stacked on the intermediate layer 120.

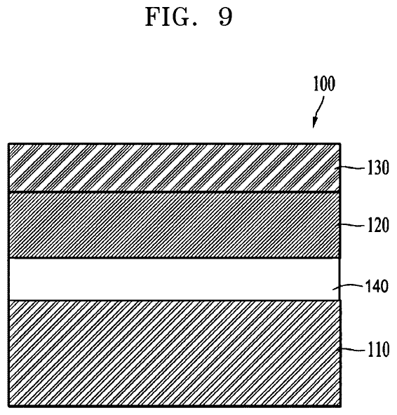

The film 100 may further include a buffer layer 140 on at least one surface of the base layer 110, as shown for example in FIG. 9. In addition, the film 100 may additionally include constituent layers in addition to the above configuration as long as a characteristic of the film 100 is not impaired. For example, a primer layer (not shown) may be formed on one surface of the base layer 110, or a release sheet (not shown) to protect the adhesive layer 130 may be additionally stacked on a surface of the adhesive layer 130. In addition, each of the base layer 110, the intermediate layer 120, and the adhesive layer 130 may have a single-layer or multi-layered structure. Moreover, the additionally included constituent layers may also form multiple layers.

### (Base Layer)

Referring to FIG. 1, according to an embodiment, the base layer 110, which is a layer having at least a predetermined level of rigidity, may suppress bending of a semiconductor wafer and may be a layer used as a basis for the formed film 100. As the base layer 110, various types of resins may be used, and specifically, a polyolefin-based single layer, or multiple layers may be used, however, embodiments are not limited thereto.

In addition, in types of polyolefin high density polyethylene (HDPE) exhibits a high density and rigidity, and an excellent chemical resistance but is inferior in terms of flexibility or processability despite an excellent rigidity, whereas low density polyethylene (LDPE) is excellent in processability, flexibility, and transparency due to a low crystallinity.

Therefore, a base layer 110, such as a polyolefin-based multi-layered base layer, may be formed by combining HDPE, LDPE, and the like, in an appropriate thickness and order to suit the purpose of the finally formed film 100. In addition, polyethylene terephthalate (PET), polyvinyl chloride (PVC), and the like may also be used as an element of the base layer 110.

The base layer 110 may increase maintenance performance of a semiconductor wafer or a semiconductor chip by the adhesive layer 130 that is to be stacked on the base layer 110, or to suppress vibration during grinding, and to prevent defects or damages of a semiconductor chip. In addition, the base layer 110 may reduce stress when the film 100 is peeled off from the semiconductor chip, to prevent some defects or damage to the semiconductor chip, which occur when the film 100 is peeled off. Furthermore, the base layer 110 may enhance a workability when the film 100 is bonded to the semiconductor wafer. Moreover, by properly setting a surface roughness and surface resistance of the base layer 110, an operation of an electrostatic chuck may be efficiently performed, and an occurrence of a transfer error may be suppressed.

A thickness of the base layer 110 may be greater than or equal to 30 μm and less than or equal to 150 μm and may desirably be greater than or equal to 50 μm and less than or equal to 100 μm, but is not limited thereto. By setting the thickness of the base layer 110 to be less than or equal to 150 μm, stress transferred to a chip in a process of picking up the film 100 including the base layer 110 may be easily controlled, and by setting the thickness of the base layer 110 to be greater than or equal to 50 μm, the film 100 may be easily supported.

The base layer 110 may additionally include a plasticizer, an ultraviolet (UV)/infrared ray absorber, an antioxidant, a dye, a catalyst, and the like, as long as the base layer 110 is not impaired.

To increase an adhesion between the base layer 110 and a neighboring layer, for example, the intermediate layer 120, the adhesive layer 130, or selectively a buffer layer 140, described further herein, an adhesive treatment may be additionally performed on at least one surface of the base layer 110.

### (Intermediate Layer)

According to an embodiment, the intermediate layer 120, which is a layer formed on one surface of the base layer 110, may correspond to a layer between the base layer 110 and the adhesive layer 130 as described herein, and may be a layer that necessarily includes polyborosiloxane (PBS).

Polyborosiloxane (PBS) is a material that may be formed by mixing polydimethylsiloxane and boric acid at a predetermined ratio and heating a mixture of the polydimethylsiloxane and the boric acid. Polyborosiloxane (PBS) may be obtained by mixing polydimethylsiloxane and boric acid at a ratio of 100 parts by weight:5 to 20 parts by weight. If an amount of the boric acid is less than 5 parts by weight that is a lower limit, a sufficient large number of functional groups required for a shear sensitivity may not be provided, and a shear sensitive characteristic may not be sufficiently exhibited due to a lack of a crosslinking point by boric acid in which a dynamic covalent bond may be formed. If the amount of the boric acid exceeds 20 parts by weight that is an upper limit, a cohesion required for an independent presence of a polyborosiloxane intermediate layer may become insufficient due to an extremely large number of boric acid ester functional group-based crosslinking points.

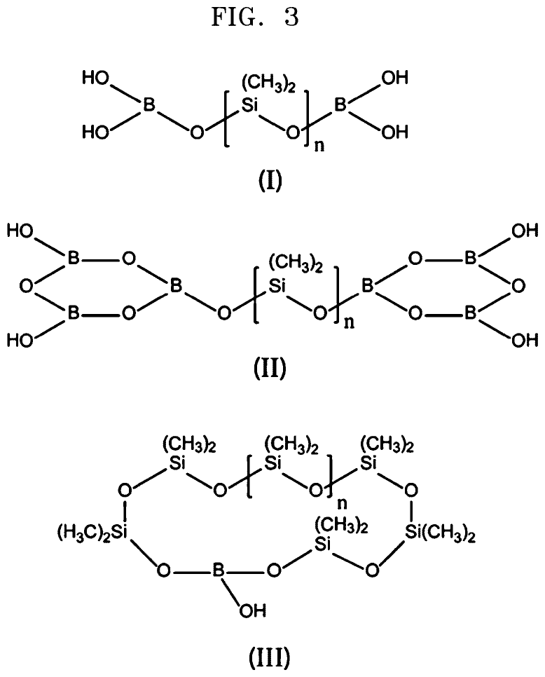

Referring to FIG. 3, the polyborosiloxane may be for example, in a form of Structural Formula (I), (II), or (III), or in a mixed form of Structural Formulae (I) and (II), a mixed form of Structural Formulae (I) and (III), a mixed form of Structural Formulae (II) and (III), or a mixed form of Structural Formulae (I), (II), and (III). The polyborosiloxane may be at least one polyborosiloxane selected from the group consisting of Structural Formula (I), (II), and (III). Because the polyborosiloxane has the above structural formulae or mixed forms thereof, the polyborosiloxane may change to a slightly viscous state in comparison to existing polyborosiloxane when a low strain is applied to polyborosiloxane that is in an equilibrium state. When a medium strain is applied, the polyborosiloxane may change to a rubbery state. In addition, when a high strain is applied, the polyborosiloxane may change to a hard state, such as a glassy state.

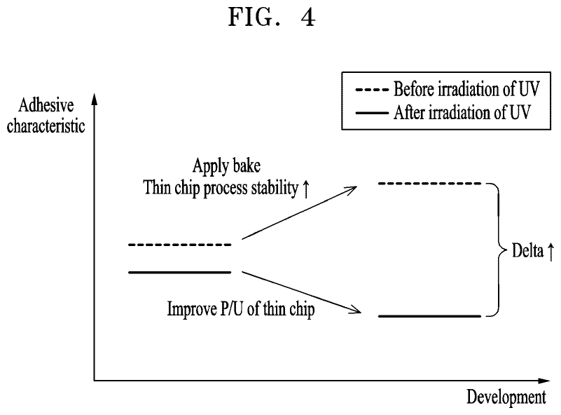

In an embodiment, polyborosiloxane having dilatant properties of increasing a viscosity due to an increase in shear stress may be used to form a film for semiconductor packaging with one or more layers, and thus, an adhesive force of the film may be effectively reduced after a shear force is added. In addition, as illustrated in FIG. 4, due to a reduction in the adhesive force caused by the addition of the shear force, a synergistic effect, along with a reduction in an adhesive characteristic through photocuring, may be exhibited, and thus, the film may be suitable for a semiconductor packaging process of a next-generation memory chip (e.g., high bandwidth memory (HBM), etc.) requiring an adhesive strength less than those of existing films.

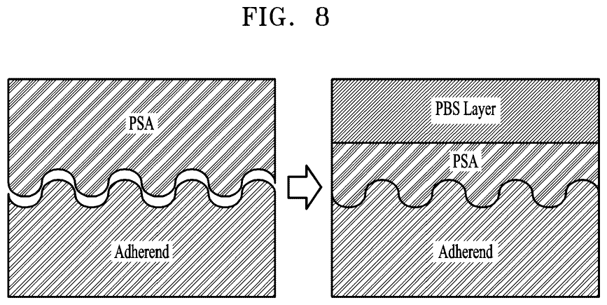

Polyborosiloxane may be used as the intermediate layer 120 of the film 100, and thus, impregnation properties of the film 100, in addition to the reduction in the adhesive force described above, may be expected. Referring to FIG. 8, polyborosiloxane may have a relatively low glass transition temperature similar to a glass transition temperature T_{g} of −125° C. of polydimethylsiloxane, which may lead to high impregnation properties of a surface of the adhesive layer 130 in the film 100 with respect to an adherend of the film 100. Thus, the film 100 with the intermediate layer 120 including the polyborosiloxane can exhibit excellent damping properties and may also reduce stress applied to a thin chip.

Because polyborosiloxane has a high solubility in an organic solvent, similarly to polydimethylsiloxane, a form, such as a polyborosiloxane gel, may be easily obtained through a solution casting by mixing and heating polydimethylsiloxane and boric acid. Thus, the polyborosiloxane may have a high applicability to the film 100.

According to an embodiment, the intermediate layer 120 may further include polydimethylsiloxane. In example embodiments polydimethylsiloxane is further mixed with polyborosiloxane (which is formed by mixing polydimethylsiloxane and boric acid). When the polydimethylsiloxane is further included as described above, an interpenetrating polymer network (IPN) may be formed with a polyborosiloxane network and a polydimethylsiloxane network. Through a formation of the IPN, physical properties of an interpenetrating polymer may be adjusted by adjusting a composition of materials, which may have an influence on physical properties of the film 100 that is finally manufactured. In addition, the polydimethylsiloxane added in addition to the polyborosiloxane may be in an amount greater than 0 parts by weight and less than or equal to 100 parts by weight, or an amount greater than or equal to 30 parts by weight and less than or equal to 70 parts by weight, based on 100 parts by weight of polyborosiloxane. If the amount of the polydimethylsiloxane exceeds 100 parts by weight, an effect of a shear sensitivity may be insignificantly exhibited because polydimethylsiloxane in a matrix of an intermediate layer is a main component.

A thickness of the intermediate layer 120 may be greater than or equal to 5 μm and less than or equal to 50 μm and may desirably be greater than or equal to 10 μm and less than or equal to 50 μm, but is not limited thereto. If the thickness of the intermediate layer 120 is set to be less than the lower limit, the above-described effect and functions that may be expected from the intermediate layer 120 including the polyborosiloxane may be absent or insufficient. If the thickness of the intermediate layer 120 exceeds the upper limit, a cohesion failure of an intermediate layer with soft physical properties during a pick-up process may occur.

### (Adhesive Layer)

According to an embodiment, the adhesive layer 130 may be formed on the intermediate layer 120 formed on one surface of the base layer 110 and may also be referred to as a “pressure sensitive adhesive (PSA) layer.”

Specifically, the PSA layer may include an active energy ray-curable adhesive, and may more specifically include an active energy ray-curable acrylic adhesive.

The expression “active energy ray” used herein may include UV or electron beams, and the active energy ray-curable adhesive may include an adhesive that may be cured when active energy rays are irradiated to the adhesive. Such an adhesive may include a thermosetting functional group, a photocurable functional group, and the like, as an adhesive composition.

An adhesive resin that may be used as an adhesive composition of an active energy ray-curable adhesive may include, for example, an acrylic resin, a urethane-based resin, a rubber-based resin, a silicon-based resin, and the like, but is not limited thereto.

Specific examples of the acrylic resin may include acrylic polymers, for example, a polymer obtained by polymerizing monomers, such as alkyl(meth)acrylate monomers.

According to an embodiment, when UV rays are irradiated using an active energy ray-curable adhesive layer, structures of polymers may be cross-linked to each other to become hard due to a reaction of a thermosetting functional group, a photocurable functional group, and the like, thereby obtaining an effect of reducing an adhesive characteristic of an adhesive after irradiation of UV rays.

Thus, in accordance with embodiments of the present invention, it is possible to obtain an effect of considerably reducing a thickness of a chip that may be used in the semiconductor packaging process, by exhibiting the synergistic effect of the reduction in the adhesive characteristic along with the addition of the shear force to the intermediate layer 120 including the polyborosiloxane, as described in detail herein.

In addition, as an adhesive composition of the adhesive layer 130, a photopolymerization initiator or a crosslinking agent may be further included in addition to the adhesive resin, such as an acrylic resin.

The photopolymerization initiator may assist a curing reaction of the adhesive composition when active energy rays are irradiated, and may allow a sufficient curing reaction to occur even when relatively low energy is irradiated, and thus, the adhesive characteristic may clearly change before and after irradiation of active energy rays and the photopolymerization initiator may be desirable in terms of process energy. The photopolymerization initiator may include any type used in the art and is not limited. For example, one photopolymerization initiator may be used or a mixture of two or more photopolymerization initiators may be used.

The crosslinking agent may assist in crosslinking of polymers to each other by assisting a reaction of a thermosetting functional group, a photocurable functional group, and the like, thereby obtaining an effect of strengthening a cohesion between polymers. Specifically, the crosslinking agent may include a thermosetting crosslinking agent, a photocurable crosslinking agent, and the like, and the specific type thereof is not limited as long as it is used in the art. In addition, one crosslinking agent may be used or a mixture of two or more crosslinking agents may be used.

A thickness of the adhesive layer 130 may be greater than or equal to 5 μm and less than or equal to 20 μm. and according to example embodiments may be greater than or equal to 10 μm and less than or equal to 15 μm, but is not limited thereto. If the thickness of the adhesive layer 130 is set to be less than a lower limit, it may be difficult to expect a great adhesive characteristic of the adhesive layer 130, or impregnation properties or adhesion to an adherend may be likely to decrease. If the thickness of the adhesive layer 130 is set to exceed an upper limit, a problem of a generation of residues of the adhesive layer 130 may occur during a separation from the adherend.

### (Buffer Layer)

According to an embodiment, as described above, a buffer layer 140 may be additionally included in the film 100, as depicted for example in FIG. 9, and may be specifically disposed on at least one surface of the base layer 110, as long as it does not impair a characteristic of the film 100.

The buffer layer 140 may correspond to a layer that is relatively soft in comparison to the base layer 110, and the type of the buffer layer is not limited if the buffer layer is typically used in the art. The buffer layer may include, for example, a polyolefin resin used for the base layer 110, or a resin including an acrylate-based compound, such as methyl methacrylate, butyl acrylate, hydroxyethyl acrylate, or urethane (meth) acrylate. The buffer layer may have a thickness of 5μ m to 100 μm, 10 μm to 80 μm, 15 μm to 50 μm, or 20 μm to 40 μm. However, the thickness is not limited thereto. By setting the thickness of the buffer layer to be within the above ranges, stress during grinding of a semiconductor wafer may be properly relieved, to prevent an occurrence of a crack or defects in the semiconductor wafer and minimize damage to a chip.

### IMPLEMENTATION EXAMPLE 2

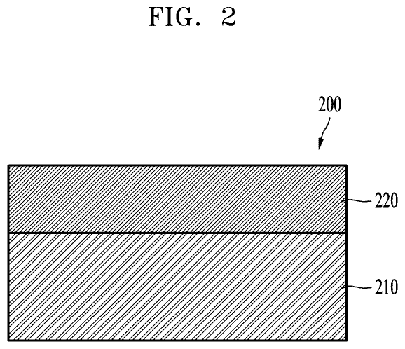

FIG. 2 is a diagram schematically illustrating another example of a film for semiconductor packaging and main components of the film according to an embodiment.

Referring to FIG. 2, in an embodiment, a film 200 for semiconductor packaging is merely an example and may be represented in the form of a laminate including a base layer 210, and an adhesive layer 220 stacked on the base layer 210.

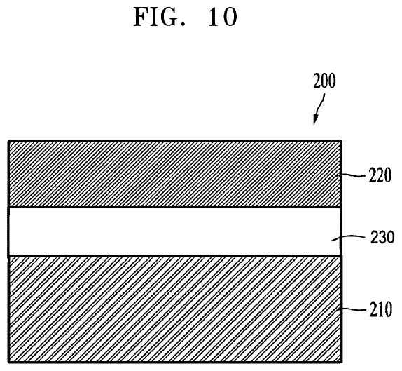

The film 200 may further include a buffer layer (230 on at least one surface of the base layer 210, as depicted for example in FIG. 10. The buffer layer 230 may be as described above with respect to buffer layer 140, relating to other embodiments herein. In addition, the film 200 may additionally include constituent layers in addition to the above configuration as long as a characteristic of the film 200 is not impaired. Furthermore, each of the base layer 210 and the adhesive layer 220 may have a single-layer or multi-layered structure. Moreover, the additionally included constituent layers may also form multiple layers.

Hereinafter, components of a film for semiconductor packaging according to an embodiment are described. Descriptions of Implementation Example 1 that overlap with descriptions in these embodiments, apply to these examples as well and are not repeated herein.

### (Base Layer)

Referring to FIG. 2, although reference numerals are different from the base layer 110 of FIG. 1, a type, a function, and a thickness of the base layer 210 included in the film 200 may be substantially the same as those of the base layer 110. Thus, further description thereof is not repeated herein, and description of the base layer 110 of FIG. 1 may equally be applied to the base layer 210 of FIG. 2.

### (Adhesive Layer)

According to an embodiment, the adhesive layer 220 may be formed on one surface of the base layer 210 and may correspond to a layer that necessarily includes polyborosiloxane. Thus, the adhesive layer 220 of FIG. 2 may substantially correspond to the intermediate layer 120 of FIG. 1, and may also correspond to a layer that may additionally perform as an adhesive layer.

The adhesive layer 220 of FIG. 2 may include a PSA in addition to polyborosiloxane. More specifically, the adhesive layer 220 may include an active energy ray-curable adhesive.

The adhesive layer 220 may be formed as a combination of the intermediate layer 120 and the adhesive layer 130 of FIG. 1. A mixing ratio of the polyborosiloxane and the active energy ray-curable adhesive can be adjusted according to a user's purpose to meet the semiconductor packaging process in which the film 200 is used, allowing for the adhesive layer to be manufactured accordingly.

A type of the active energy ray-curable adhesive included in the adhesive layer 220 may be substantially the same as that of the adhesive layer 130 of FIG. 1 described herein. In addition, a photopolymerization initiator or a crosslinking agent may be additionally included so that a crosslinking reaction of a thermosetting functional group or a photocurable functional group or a curing reaction of an adhesive composition may easily occur.

In addition, the adhesive layer 220 may further include polydimethylsiloxane together with the polyborosiloxane, to form an interpenetrating polymer network (IPN), and may adjust physical properties of an interpenetrating polymer by adjusting an amount of the polydimethylsiloxane.

A thickness of the adhesive layer 220 may be for example, a sum of the thickness of the intermediate layer 120 and the thickness of the adhesive layer 130 of FIG. 1, and may be greater than or equal to 5 μm and less than or equal to 50 μm, greater than or equal to 10 μm and less than or equal to 30 μm, or greater than or equal to 10 μm and less than or equal to 20 μm, but is not limited thereto. If the thickness of the adhesive layer 220 is set to be less than a lower limit, it may be difficult to expect a great adhesive characteristic of the adhesive layer 220, or impregnation properties or adhesion to an adherend may be likely to decrease. If the thickness of the adhesive layer 220 is set to exceed an upper limit, a problem of a generation of residues of the adhesive layer 220 may occur during a separation from the adherend.

In Implementation Example 2 in which the adhesive layer 220 is stacked on the base layer 210, a relatively thin film may be manufactured in comparison to Implementation Example 1 in which the base layer 110, the intermediate layer 120, and the adhesive layer 130 are stacked.

### Method of Manufacturing Film for Semiconductor Packaging

According to an embodiment, a method of manufacturing a film for semiconductor packaging is provided.

The method may include preparing a base layer having a first base layer surface and a second base layer surface. A type and a thickness of the base layer may be substantially the same as those of the base layer 110 described herein.

When the base layer is prepared, at least one of the first base layer surface or the second base layer surface may be coated with a polyborosiloxane composition, and drying of the polyborosiloxane may be performed, to form an intermediate layer on the base surface. The coating may include coating the base layer 110, or coating a layer that is over the base layer, such as a buffer layer 140.

The forming of the intermediate layer may include a process of forming the polyborosiloxane composition by mixing polydimethylsiloxane and boric acid at a ratio of 100 parts by weight:5 to 20 parts by weight to form a mixture of polydimethylsiloxane and boric acid, and heating the mixture of the polydimethylsiloxane and the boric acid, to manufacture a film for semiconductor packaging with desired physical properties, specifically, to adjust physical properties of the intermediate layer.

Here, the heating may be performed at a temperature of 140° C. to 180° C., 150° C. to 170° C., or about 160° C., for 10 to 30 minutes, 15 to 25 minutes or for about 20 minutes. The polyborosiloxane composition prepared through the above process may be in a form of a gel, and a form of Structural Formula (I), (II), or (III), a mixed form of Structural Formulae (I) and (II), a mixed form of Structural Formulae (I) and (III), a mixed form of Structural Formulae (II) and (III), or a mixed form of Structural Formulae (I), (II), and (III), as illustrated in FIG. 3.

In addition, an operation of additionally mixing polydimethylsiloxane with the polyborosiloxane composition formed as described above and performing coating and drying may also be included.

To form an IPN with a polyborosiloxane network and a polydimethylsiloxane network, the polydimethylsiloxane may be additionally mixed. For example, forming the intermediate layer may include mixing polydimethylsiloxane with the polyborosiloxane composition before performing a coating step and a drying step. In example embodiments, the coating includes coating at least one of a first base layer surface or the second base layer surface with the mixture of the polydimethylsiloxane and the polyborosiloxane composition. The drying step includes drying the polydimethylsiloxane and the polyborosiloxane composition.

Thus, physical properties of an interpenetrating polymer may be adjusted, to adjust physical properties of the film for semiconductor packaging that is manufactured.

Similar methods of manufacturing a film for semiconductor packaging are included that include preparing a base layer having a first base layer surface and a second base layer surface and forming an adhesive layer on at least one of the first base layer surface or the second base layer surface. According to example embodiments, the adhesive layer includes a polyborosiloxane composition as described herein. As with other embodiments, the polyborosiloxane composition may be formed by mixing polydimethylsiloxane and boric acid at a ratio of 100 parts by weight:5 to 20 parts by weight to form a mixture of polydimethylsiloxane and boric acid, and heating the mixture of the polydimethylsiloxane and the boric acid, to manufacture a film for semiconductor packaging with desired physical properties.

Additional methods included herein, may include for example, adding a buffer layer to one or more of the method embodiments herein. Example methods may include for example, forming a buffer layer on at least one surface of the base layer, forming an intermediate layer by coating the buffer layer, and forming an adhesive layer on the intermediate layer. Example methods may also include for example, forming a buffer layer on at least one surface of the base layer, and forming an adhesive layer including polyborosiloxane on the buffer layer.

A scheme of coating the surface of the base layer may be used without limitation, as long as it is widely known in the art, and may include, for example, comma coating, spin-on coating, slit coating, bar coating, or spray coating. After the coating, the film may be passed through an elongated drying chamber to be dried.

Examples in which a film for semiconductor packaging according to an embodiment is applied are described. However, the following application examples are merely examples in which a film for semiconductor packaging is applicable, and embodiments within the scope of the invention are not limited thereto.

### APPLICATION EXAMPLE 1 (DICING TAPE)

A dicing tape may be used to fix a semiconductor wafer to prevent the semiconductor wafer from being misaligned when a semiconductor wafer thinned by grinding is cut into a desired size using a dicing blade, and the like, and singulated into cut semiconductor chips.

In addition, when a dicing process is terminated, thermocuring energy may be irradiated to the dicing tape to reduce an adhesive force. The dicing tape may be selectively chilled and expanded, and a chip may be picked up using an ejector and air blowing. The dicing tape may both attach to and detach from an adherend.

Referring to FIG. 4, it can be found that as a change in an adhesive characteristic before and after irradiation of UV rays increases, a suitability for use as a dicing tape increases, and that, to manufacture a thin semiconductor chip, the dicing tape is being developed such that a change (delta) in an adhesive characteristic before and after irradiation of UV rays increases.

In addition, as the number of stacked layers of HBM increases, a thickness of a chip may decrease. Thus, the adhesive strength required to prevent cracks of the chip from occurring during a pick-up process also may need to be significantly reduced in comparison to the current level.

Therefore, the required characteristics of the dicing tape include thinness, significant differences in adhesive strength before and after UV irradiation, which effectively reduce or prevent crack formation during semiconductor chip pickup, and damping for stress reduction in thin chip thickness.

Hence, a film for semiconductor packaging including polyborosiloxane according to an embodiment may enhance impregnation properties before a shear force is added, reduce the adhesive characteristic due to an addition of the shear force, and may have a damping effect due to a characteristic of a dilatant material, in addition to a photocuring strategy for an activated energy ray-curable adhesive composition, thereby improving a pick-up characteristic of a thin semiconductor chip, such as HBM, and the like.

In addition, according to an embodiment, to facilitate a transfer to a die bonding process after the pick-up process, the film may also be used as a die bonding tape in which a die bonding adhesive is additionally stacked between an adhesive layer and a base layer.

### APPLICATION EXAMPLE 2 (BACKGRINDING TAPE)

A backgrinding tape is typically a film used to protect a circuit face of a semiconductor wafer while stably fixing the semiconductor wafer in a backgrinding process.

A film for semiconductor packaging according to an embodiment may also be used as a backgrinding tape.

More specifically, the film for semiconductor packaging according to an embodiment may be bonded to a surface of a semiconductor wafer on which a circuit is formed, to fix the semiconductor wafer, and then grinding may be performed on a back surface of the semiconductor wafer using a grinding wheel to achieve a desired thickness of the semiconductor wafer while spraying water. When the grinding is terminated, a shear force may be applied to the bonded film to reduce the adhesive force, and the backgrinding tape may be peeled off from the ground semiconductor wafer. In addition, an active energy ray-curable adhesive may be used as an adhesive layer of a film for semiconductor packaging according to an embodiment, as described above, and thus, the shear force may be added to the film to more effectively reduce the adhesive force, and at the same time, active energy rays, such as ultraviolet rays, may be irradiated, so that the film may be easily peeled off.

Recently, in response to a continuous requirement to decrease the thickness of a multi-layered memory chip, such as HBM, grinding may be required in the backgrinding process to obtain a semiconductor wafer thinner than existing semiconductor wafers. To obtain such a thin semiconductor wafer, a thickness of a film for semiconductor packaging that may be used as the backgrinding tape may also need to be uniform. When a uniformity of a thickness of the backgrinding tape is taken into consideration, a polyester-based resin composition that may ensure a thickness uniformity may be used as a base layer of a film for semiconductor packaging according to an embodiment.

In addition, the film 100, 200 for semiconductor packaging may also be used as a lamination tape or a protection tape and may be applicable in various ways to all semiconductor packaging processes requiring impregnation properties and shear stress-sensitive performance, and embodiments are not limited to the application examples described above.

The effects to be achieved are not limited to those described above, and other effects not mentioned above will be clearly understood by one of ordinary skill in the art from this document. The foregoing is illustrative of example embodiments and is not to be construed as limiting thereof. Although example embodiments have been described, those skilled in the art will readily appreciate that many modifications are possible in some example embodiments without materially departing from the novel teachings and advantages of the present invention. Accordingly, all such modifications are intended to be included within the scope of the invention as defined in the claims.

What is claimed is:

1. A film for semiconductor packaging, the film comprising:
a base layer;
an intermediate layer; and
an adhesive layer,
wherein the intermediate layer comprises polyborosiloxane.

2. The film of claim 1, wherein the intermediate layer further comprises polydimethylsiloxane.

3. The film of claim 2, wherein the polydimethylsiloxane is included in an amount greater than 0 parts by weight and less than or equal to 100 parts by weight based on 100 parts by weight of the polyborosiloxane in the intermediate layer.

4. The film of claim 1, further comprising:
a buffer layer on at least one of a first base layer surface or a second base layer surface of the base layer.

5. The film of claim 1, wherein the base layer has a thickness of 30 μm to 150 μm.

6. The film of claim 1, wherein the intermediate layer has a thickness of 5 μm to 50 μm.

7. The film of claim 1, wherein the adhesive layer has a thickness of 5 μm to 20 μm.

8. The film of claim 1, wherein the base layer is a polyolefin-based base layer.

9. The film of claim 1, wherein the adhesive layer comprises a pressure sensitive adhesive (PSA).

10. The film of claim 1, wherein the adhesive layer comprises an active energy ray-curable acrylic adhesive.

11. The film of claim 1, wherein the film is a dicing tape, a backgrinding tape, a lamination tape, or a protection tape.

12. The film of claim 1, wherein the polyborosiloxane is prepared by mixing polydimethylsiloxane and boric acid at a ratio of 100 parts by weight:5 to 20 parts by weight to form a mixture of the polydimethylsiloxane and the boric acid, and heating the mixture of the polydimethylsiloxane and the boric acid.

13. A film for semiconductor packaging, the film comprising:
a base layer; and
an adhesive layer,
wherein the adhesive layer comprises polyborosiloxane.

14. The film of claim 13, wherein
the adhesive layer further comprises polydimethylsiloxane; and
the polydimethylsiloxane is included in an amount greater than 0 parts by weight and less than or equal to 100 parts by weight, based on 100 parts by weight of the polyborosiloxane in the adhesive layer.

15. The film of claim 13, wherein the adhesive layer further comprises an active energy ray-curable acrylic adhesive.

16. The film of claim 13, wherein the adhesive layer has a thickness of 5 μm to 50 μm.

17. The film of claim 13, wherein the polyborosiloxane is prepared by mixing polydimethylsiloxane and boric acid at a ratio of 100 parts by weight:5 to 20 parts by weight, to form a mixture of the polydimethylsiloxane and the boric acid, and heating the mixture of the polydimethylsiloxane and the boric acid.

18. A method of manufacturing a film for semiconductor packaging, comprising:
preparing a base layer having a first base layer surface and a second base layer surface;
forming an intermediate layer by coating at least one of the first base layer surface or the second base layer surface with a polyborosiloxane composition and drying the polyborosiloxane; and
forming an adhesive layer on the intermediate layer.

19. The method of claim 18, wherein the forming of the intermediate layer comprises forming the polyborosiloxane composition by
mixing polydimethylsiloxane and boric acid at a ratio of 100 parts by weight:5 to 20 parts by weight to form a mixture of the polydimethylsiloxane and the boric acid, and
heating the mixture of the polydimethylsiloxane and the boric acid.

20. The method of claim 18, wherein, forming of the intermediate layer, further comprises:
mixing polydimethylsiloxane with the polyborosiloxane composition to form a mixture of the polydimethylsiloxane and the polyborosiloxane composition, and
performing the coating step and the drying step;
wherein the coating step comprises coating at least one of the first base layer surface or the second base layer surface with the mixture of the polydimethylsiloxane and the polyborosiloxane composition; and
wherein the drying step comprises drying the polydimethylsiloxane and the polyborosiloxane composition.
